(19) United States
(12) Patent Application Publication
(10) Pub. No.: US 2018/0040496 A1
(43) Pub. Date: Feb. 8, 2018

(54) ELECTROSTATIC CHUCK SYSTEM AND CONTROL METHOD THEREOF

(71) Applicant: SAMSUNG ELECTRONICS CO., LTD., Suwon-si (KR)

(72) Inventors: Chunghun LEE, Hwaseong-si (KR); Janghwan KIM, Suwon-si (KR); Kwanghyun CHO, Yongin-si (KR); Youngho HWANG, Hwaseong-si (KR)

(21) Appl. No.: 15/475,622

(22) Filed: Mar. 31, 2017

(30) Foreign Application Priority Data
Aug. 4, 2016 (KR) 10-2016-0099592

(51) Int. Cl. H01L 21/683; H05B 3/22; H01L 21/67; H05B 1/02

(52) U.S. Cl. CPC H01L 21/6833; H05B 1/0233; H05B 3/22; H01L 21/67103; H01L 21/67248; H05B 2203/035

(57) ABSTRACT

An electrostatic chuck system includes a first heater, a second heater, a chiller, and a controller. The first heater includes a plurality of resistors connected to a plurality of row wiring lines and a plurality of column wiring lines in a matrix form. The second heater includes a heater electrode in a concentric shape or a spiral shape. The chiller chills the first heater or the second heater. The controller controls the first heater, the second heater, and the chiller. The controller switches the row wiring lines and the column wiring lines of the first heater in a time-division manner to provide a power pulse to heat the resistors and a detect pulse to monitor a real-time resistance value or a real-time temperature of each of resistors connected to selected row wiring lines.

### CROSS-REFERENCE TO RELATED APPLICATION

Korean Patent Application No. 10-2016-0099592, filed on Aug. 4, 2016, and entitled, “Electrostatic Chuck System and Control Method Thereof,” is incorporated by reference herein in its entirety.

### BACKGROUND

### 1. Field

One or more embodiments described herein relate to an electrostatic chuck system and a method for controlling an electrostatic chuck system.

### 2. Description of the Related Art

Semiconductor manufacturing equipment is used to perform various processes on a wafer. The position of the wafer in a processing chamber should be fixed to provide stability. An electrostatic chuck may be used to fix the wafer.

One type of electrostatic chuck includes a heater and chiller to control wafer temperature during a semiconductor process. The heater includes an array of resistors in a matrix. Each resistor blocks power interference or power coupling with a physically adjacent resistor using a diode. However, the resistor array may be sintered at a high temperatures during mass production. The diode may be adversely affected or modified at these high temperatures, thus diminishing wafer reliability.

### SUMMARY

In accordance with one or more embodiments, an electrostatic chuck system includes a first heater including a plurality of resistors connected to a plurality of row wiring lines and a plurality of column wiring lines in a matrix form; a second heater under the first heater and including a heater electrode in a concentric shape or a spiral shape; a chiller under the second heater to chill the first heater or the second heater; and a first controller to control the first heater, the second heater, and the chiller, wherein the first controller is to switch the row wiring lines and the column wiring lines of the first heater in a time-division manner to provide a power pulse to heat the resistors and a detect pulse to monitor a real-time resistance value or a real-time temperature of each of resistors connected to selected row wiring lines.

In accordance with one or more other embodiments, a method for controlling a heater array, which includes a plurality of resistors arranged in a matrix, each of the resistors excluding and is not connected to a semiconductor rectifying device, the method comprising: computing a duty time of each of a plurality of row switches and a plurality of column switches based on mutual power coupling of the resistors, the row and column switches supplying electric power to heat each of the resistors; applying electric power to the resistors by sequentially turning on the row switches and the column switches based on the duty time; applying a detect pulse to each of the resistors; and estimating a real-time resistance value or a real-time temperature of each of the resistors with reference to the detect pulse.

In accordance with one or more other embodiments, an electrostatic chuck system including an electrostatic chuck includes a micro heater and a macro heater, the micro heater including a plurality of resistors connected in a matrix form and the macro heater including a heater electrode in a concentric shape or a spiral shape; and a controller to control heating power to the micro heater or the macro heater, wherein the controller is to provide a time-division power pulse, to which mutual power coupling among the resistors is applied, provide a detect pulse to detect a characteristic change of each of the resistors, and update a pulse width of the power pulse based on a response to the detect pulse.

In accordance with one or more other embodiments, an electrostatic chuck system including a first heater including a plurality of resistors; a second heater adjacent to the first heater; a chiller adjacent to the second heater; and a controller to control the first heater, the second heater, and the chiller, wherein the resistors exclude and are not connected to semiconductor rectifying devices and wherein the controller is to generate control information to control heat to be generated from the resistors.

### BRIEF DESCRIPTION OF THE DRAWINGS

Features will become apparent to those of skill in the art by describing in detail exemplary embodiments with reference to the attached drawings in which:

FIG. 1 illustrates an embodiment of an electrostatic chuck system;

FIG. 2 illustrates an embodiment of an electrostatic chuck;

FIG. 3 illustrates an embodiment of a micro heater and a micro driver;

FIG. 4 illustrates current paths formed according to an embodiment;

FIG. 5 illustrates a determinant illustrating a relationship between duty times of switch control signals, whole electric power, and power consumption according to an embodiment;

FIG. 6 illustrates power pulses according to an embodiment;

FIGS. 7A-7D illustrate an embodiment of a method for applying a detect pulse to a heater array;

FIG. 8 illustrates an embodiment of a method for driving a micro heater;

FIG. 9 illustrates an embodiment of an operation of the method in FIG. 8;

FIG. 10 illustrates another embodiment of a method for driving a micro heater;

FIG. 11 illustrates another embodiment of a micro heater and micro driver;

FIG. 12 illustrates a determinant of a duty time of a power pulse for controlling a micro heater in FIG. 11 according to an embodiment;

FIG. 13 illustrates another embodiment of a micro heater;

FIG. 14 illustrates an embodiment of independent heater arrays of a micro heater; and

FIGS. 15 and 16 illustrate embodiments of a method for arranging resistors of a micro heater.

### DETAILED DESCRIPTION

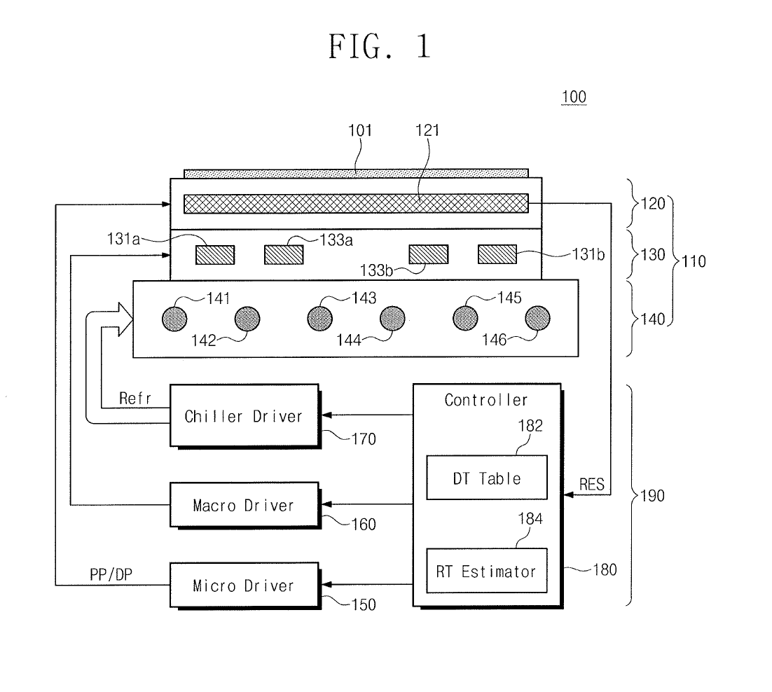

FIG. 1 illustrates a cross-sectional view of an embodiment of an electrostatic chuck system 100 which includes an electrostatic chuck 110 and a control unit 190. The electrostatic chuck 110 may include a micro heater 120, a macro heater 130, and a chiller 140. The control unit 190 may include a micro driver 150, a macro driver 160, a chiller driver 170, and a controller 180.

A wafer 101 may be fixed on the electrostatic chuck 110. For example, an electrostatic force may fix the wafer 101 to the electrostatic chuck 110 when a high constant voltage is applied to the electrostatic chuck 110. The electrostatic chuck 110 may compensate for a temperature deviation between areas on the wafer 101 through the micro heater 120, the macro heater 130, and the chiller 140.

The micro heater 120 may include a heater array 121 in a matrix structure. The heater array 121 which may finely adjust the temperature of a target point without using a semiconductor device, e.g., a diode or transistor. In one embodiment, a plurality of resistors, arranged in a row direction and a column direction, generate heat based on applied electric power. A power pulse having a certain duty time or a duty ratio may be provided to a resistor at an intersection of a selected row and a selected column of the micro heater 120. The power pulse may be provided through the micro driver 150.

The resistors of the micro heater 120 may have, for example, the same resistance value. However, characteristics of the resistors of the micro heater 120 may vary as the result of error in a manufacturing process and real-time peripheral environment effects. The change in characteristics of the resistors may cause, for example, the resistance value of a resistor to change or may effect a temperature changer or heat to be generated.

According to an embodiment, a detect pulse DP for estimating a real-time resistance value or a real-time temperature is applied to the resistors of the micro heater 120. The controller 180 receives a result obtained based on applying the detect pulse DP. The controller 180 may estimate a real-time resistance value or a real-time temperature of each resistor of the micro heater 120 through the detect pulse DP. The controller 180 may then adjust the duty time of the power pulse based on the estimated real-time resistance value or the estimated real-time temperature.

The macro heater 130 may control the temperature of a relatively wide area compared to the micro heater 120. In one embodiment, the macro heater 130 may include a heater electrode formed according to a geometric shape of the electrostatic chuck 110. For example, the macro heater 130 may include a heater electrode having a spiral or concentric shape, instead of a point shape. In one embodiment, the macro heater 130 may include heater electrodes of an array shape for heating a wider area than an area heated by the micro heater 130.

In one embodiment, the macro heater 130 may have a heater electrode with a concentric shape. For example, the macro heater 130 may include heater electrodes 131a, 131b, 133a, and 133b arranged in a concentric direction in the electrostatic chuck 110 having a disk shape. The heater electrodes 131a and 131b indicate resistor sections forming one concentric circle (e.g., an outer concentric circle). The heater electrodes 133a and 133b indicate resistor sections forming an inner concentric circle. The number of heater electrodes in a concentric shape or the arrangement shape of the heater electrodes may be different in other embodiments, for example, based on the kind of semiconductor process, a wafer size, or other factors.

The chiller 140 chills the electrostatic chuck 110 when heated to a high temperature. The electrostatic chuck 110 may be used, for example, in a plasma processing apparatus that processes the wafer 110 using plasma. When the interior of a chamber in which the electrostatic chuck 110 is installed is set in a high-temperature environment and the wafer 101 is exposed to high-temperature plasma, the wafer 101 may be experience damage, for example, from ion bombardment. Thus, the wafer 101 may be chilled by the chiller 140 to prevent the wafer 101 from being damages and to allow for uniform plasma processing.

In order to chill the wafer 101, a refrigerant flows through channels 141 to 146 in the chiller 140. The refrigerant may include, for example, water, ethylene glycol, silicon oil, liquid Teflon, or a mixture of water and glycol. In addition to the refrigerant, the channels 141 to 146 may be implemented with thermoelectric cooling devices to adsorb peripheral heat according to applied electric power. The chiller 140 may be provided with the refrigerant from the chiller driver 170 and/or with cooling power under control of the controller 180.

Cooling or heating of the electrostatic chuck 110 may be controlled by the control unit 110, that includes the micro driver 150, the macro driver 160, the chiller driver 170, and the controller 180.

The micro driver 150 provides the micro heater 120 with a power pulse PP having a pulse width controlled by the controller 180. The micro driver 150 may provide the power pulse PP to each of the resistors of the heater array 121. The power pulse PP has a duty time DT and is provided under control of the controller 180 The micro driver 150 may include a switch unit that selects rows and columns of the heater array 121. The switching time of each switch of the switch unit may be determined according to the duty time DT calculated in the controller 180 or may be predetermined.

The macro driver 160 adjusts the temperature of the macro heater 130 under control of the controller 180. The macro driver 160 may perform temperature adjustment on areas of a relatively wide range compared to the micro heater 120. For example, under control of the controller 160, the macro driver 160 may supply electric power to the heater electrodes 131a, 131b, 133a, and 133b in the concentric direction. The macro driver 160 may provide electric power of different levels to the heater electrodes 131a and 131b, which constitute an outer concentric circle, and the heater electrodes 133a and 133b, which constitute an inner concentric circle.

The chiller driver 170 may pump the refrigerant into the channels 141 to 146 under control of the controller 180. For example, the chiller driver 170 may uniformly supply the refrigerant to the chiller 140 to maintain temperature equilibrium of the chamber. The chiller driver 170 may include, for example, a pump to pressurize fluid such as a refrigerant. When the chiller 140 includes a cooling device that adsorbs peripheral heat by electric energy, the chiller driver 170 may supply or switch electric power under control of the controller 180.

To adjust a temperature of the electrostatic chuck 110, the controller 180 may control the micro driver 150, the macro driver 160, and the chiller driver 170. The controller 180 may be, for example, a management server or computer that controls a semiconductor manufacturing process. The controller 180 may monitor the state of the electrostatic chuck 110 and may control the micro driver 150, the macro driver 160, and the chiller driver 170 based on the monitoring result. In addition, the controller 180 may monitor a real-time resistance value or temperature of each heater electrode with reference to a response RES of the micro heater 120 to the detect pulse DP. The controller 180 may compensate a temperature of a specific area or a resistance value of a heater electrode using the above-described monitoring result.

The controller 180 may include a duty time table 182 and a temperature/resistance estimator 184. The duty time table 182 stores the duty time DT, which, for example, may be indicative of the width of the power pulse PP applied to resistors in each area of the micro heater 120. The duty time DT of the power pulse PP may be determined, for example, based on interferences among the resistors of the micro heater 120. The duty time DT may be stored in the duty time table 182 and periodically updated. The temperature/resistance estimator 184 may estimate a real-time resistance value or a real-time temperature of the micro heater 120 with reference to the response RES to the detect pulse DP. The temperature/resistance estimator 184 computes the duty time DT to compensate for the real-time resistance value or real-time temperature of each resistor of the micro heater 120. The controller 180 may update the duty time table 182 with the computed duty time. Afterwards, the power pulse PP to be provided to the micro heater 120 may be generated based on the updated duty time DT.

The electrostatic chuck system 100 may include the micro heater 120 that does not include a semiconductor device. In addition, the electrostatic chuck system 100 may provide the power pulse PP determined based on the power coupling among resistors in the heater array 121. Also, the electrostatic chuck system 100 may provide the detect pulse DP for monitoring a resistance value or a real-time temperature of each resistor in the heater array 121. The electrostatic chuck system 100 may periodically update duty time information of the power pulse PP, which the micro driver 150 supplies, with reference to a response to the detect pulse DP.

In accordance with the present embodiment, the electrostatic chuck 110 may not use a semiconductor device such as a diode or temperature sensor for measuring a temperature of a specific time point. Thus, the electrostatic chuck system 100 may have the ability achieve control at high temperatures and with a simple design.

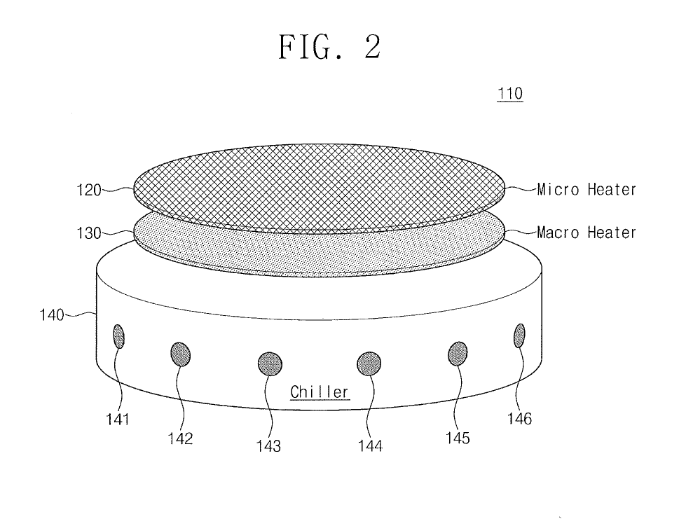

FIG. 2 illustrates an embodiment of the electrostatic chuck 110 including the micro heater 120, the macro heater 130, and the chiller 140 in a disk shape. The electrostatic chunk 110 may further include an adsorption electrode on or over the micro heater 120 to adsorb the wafer 101 (refer to FIG. 1) with the electrostatic force when a constant voltage is provided. An electrostatic dielectric for providing electrical isolation may be between the adsorption electrode and the micro heater 120. An electrical isolation material having a specific thermal conductivity may be between the micro heater 120 and the macro heater 130. Materials having predetermined thermal conductivities corresponding to a desired application may be between the macro heater 130 and the chiller 140.

In the above-described structure, a uniform temperature distribution may be generated on the entire area of the wafer 101 using the micro heater 120 and the macro heater 130. For example, as the temperature of a specific area of the micro heater 120 increases, it may be difficult to maintain a target temperature (e.g., even when the power pulse PP is almost not supplied). In the case, the temperature may be reduced by activating the chiller 140. Based on the reduced temperature, dynamic temperature control may be performed through coarse temperature control of the macro heater 130 and fine temperature control of the micro heater 120.

The electrostatic chuck 110 includes the chiller 140 and a dual heater of the micro heater 120 and the macro heater 130 with heater electrodes of different control ranges and shapes. In another embodiment, the number of heaters and/or number of chillers may be different (e.g., more or less) based on the intended application.

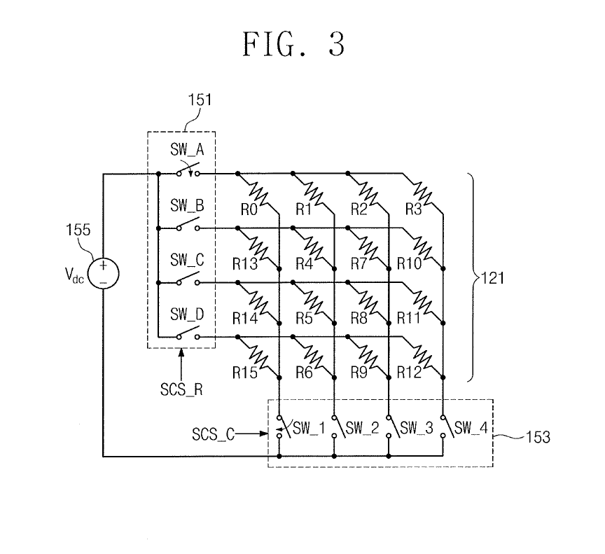

FIG. 3 illustrates a combination of the micro heater 120 and the micro driver 150 according to an embodiment. The heater array 121 includes a plurality of resistors arranged in rows and columns, a row switch 151 for selecting the rows, a column switch 153 for selecting the columns, and a voltage source 155. In this example, the heater array 121 includes 16 resistors R0 to R15 arranged in a 4-by-4 matrix. Each of the resistors R0 to R15 of the heater array 121 may not include a semiconductor rectifying device. e.g., a diode. Accordingly, the heater array 121 may be easy to manufacture and may have a uniform physical characteristic. The heater array 121 may have a different number of resistors in another embodiment.

The row switch 151 and the column switch 153 select the rows and columns of the heater array 121, respectively. Switches SW_A, SW_B, SW_C, and SW_D of the row switch 151 are controlled by a first switch control signal SCS_R from the controller 180. Switches SW_1, SW_2, SW_3, and SW_4 of the column switch 153 are controlled by a second switch control signal SCS_C from the controller 180.

The voltage source 155 may be connected with a plurality of resistors by the row switch 151 and the column switch 153. For example, the switch SW_A and the switch SW_1 may be simultaneously turned on by the first switch control signal SCS_R and the second switch control signal SCS_C.

In the case where a rectifying device (e.g., a diode) is connected to each of the resistors R0 to R15, only resistor R0 selected by the switches SW_A and SW_1 may be supplied with electric power after being connected to the voltage source 155. However, when a rectifying device is not included, various current paths may be formed between the switch SW_A and the switch SW_1. Power consumption or heat generation occurs at each of resistors through which a current path is formed. Each of the switch control signals SCS_R and SCS_C may include a pulse to compensate for the above-described power interference.

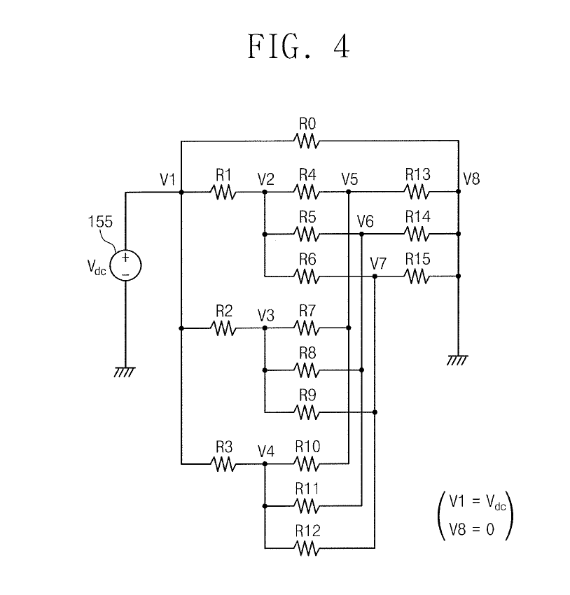

FIG. 4 illustrates an embodiment of equivalent circuit diagram of various current paths that may be formed when the switches SW_A and SW_1 of FIG. 3 are turned on. Referring to FIG. 4, the level of a voltage across each of the resistors R0 to R15 may be computed at a time point at which the switches SW_A and SW_1 are turned on. The electric power consumed by the respective resistors R0 to R15 may be computed by the voltages across the resistors R0 to R15.

In one embodiment, the electric power consumed by the resistor R0 at a time point at which the switches SW_A and SW_1 are turned on may be computed by (V1−V8)²/R0. The electric power consumed by the resistor R4 at a time point at which the switches SW_A and SW_1 are turned on may be computed by (V2−V5)²/R4. Voltages V1 to V8 of nodes corresponding to opposite ends of the respective resistors R0 to R15 may be computed, for example, using algorithms based on circuit analysis theory. The electric power consumed by each of the resistors R0 to R15 may be expressed as a magnitude relative to the entire electric power P_{ON} supplied to the heater array 121.

The electric power applied to each of the resistors R0 to R15 may be converted by Joule heating to thermal energy. An area corresponding to each of the resistors R0 to R15 is heated by the Joule heating. The temperature of each of the resistors R0 to R15 is controlled by controlling the turn-on time of corresponding ones of the row and column switches 151 and 153. In addition, if the electric power consumed by each of the resistors R0 to R15 is known through a combination of the row switch 151 and the column switch 153, the turn-on times of the row switch 151 and the column switch 153 may be calculated to maintain a target temperature.

In the present embodiment, the electric power consumed by each of the resistors R0 to R15 may be computed to maintain a specific temperature, with respect to all combinations of the row switch 151 and the column switch 153. The switch control signals SCS_R and SCS_C for providing a turn-on period for each combination of the row switch 151 and the column switch 153 may be provided with reference to the computed electric power. In this case, the power pulse PP, to which the power coupling is applied, may have a duty time set to correspond to a pulse width of each of the switch control signals SCS_R and SCS_C.

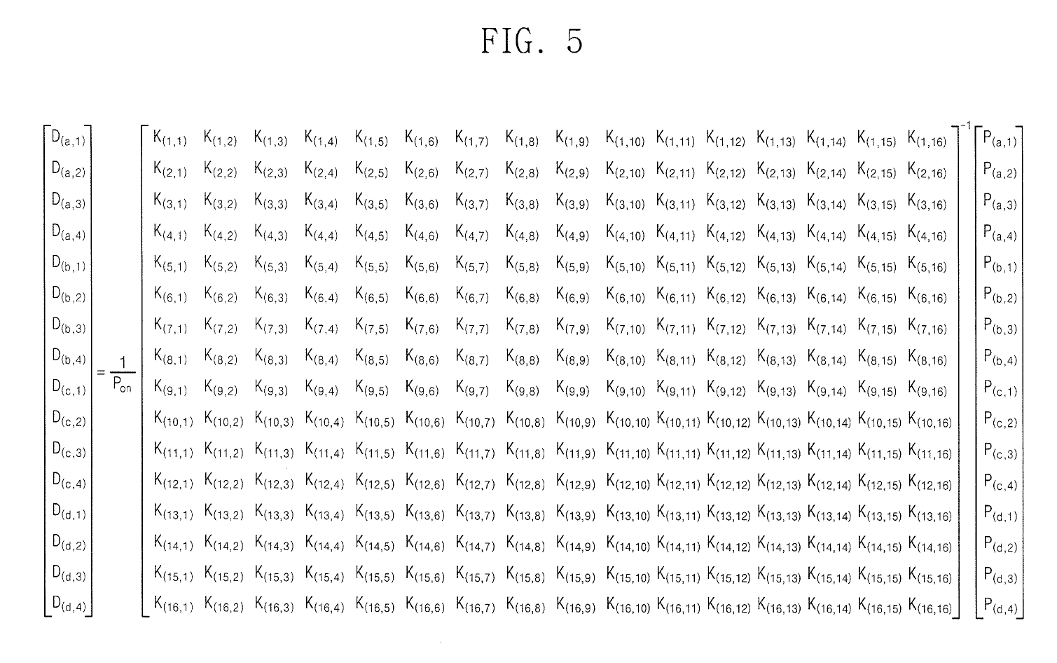

FIG. 5 illustrates a determinant corresponding to a relationship between duty times of the switch control signals SCS_R and SCS_C, to which the power coupling of the heater array 121 of FIG. 3 is applied, the entire electric power PON, and power consumption of each resistor. Duty times D(a,1), D(a,2), . . . , D(d,4) of the switch control signals SCS_R and SCS_C for controlling all switches of the row switch 151 and the column switch 153 nay correspond to FIG. 5.

In this embodiment, the electric power P₁ consumed by the resistor R1 under the condition of FIG. 4 may be expressed by Equation 1.

$${P}_{1} = \frac{{( V 1 - V 2 )}^{2}}{R 1} = {K}_{( 1 , 1 )} {P}_{on} \qquad ( 1 )$$

In Equation 1, K_{(1,1)} indicates a ratio of electric power consumed by a resistor at the first row and first column. Electric power P₀ and P₂ to P₁₅ consumed by the remaining resistors R0 and R2 to R15 may be respectively expressed by a value relative to the entire electric power P_{ON}. According to Equation 1, the duty times of the switch control signals SCS_R and SCS_C may be computed based on mutual power interference using the electric power to heat each resistor. Since the determinant is used for iterative computation, the determinant may depend on computation of a computer.

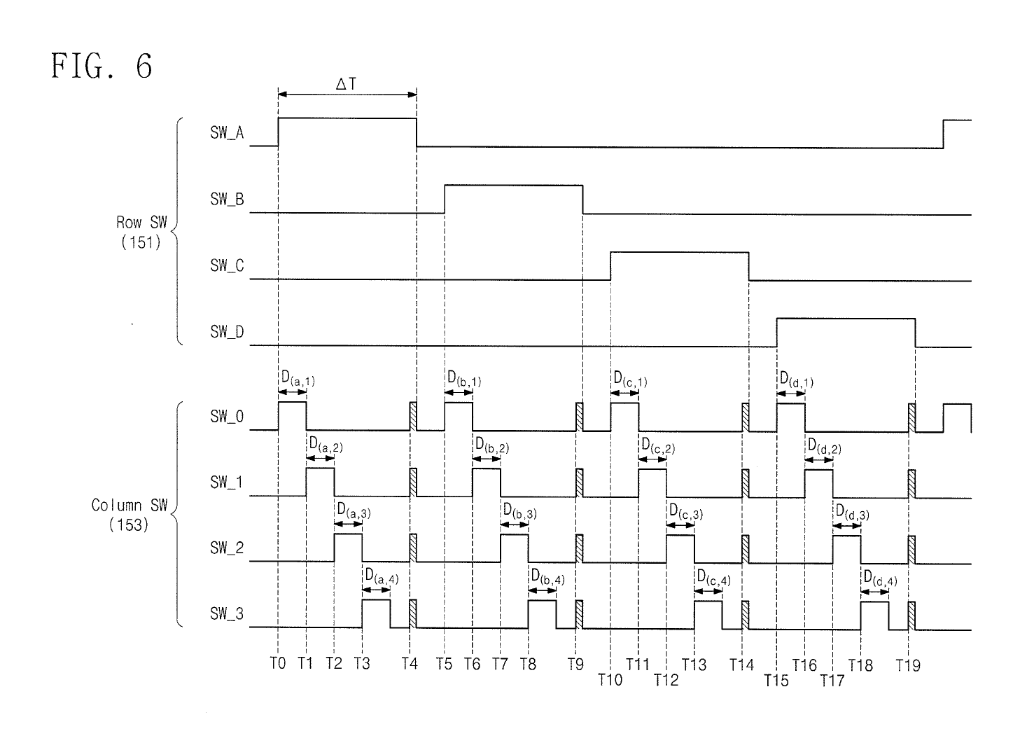

FIG. 6 illustrates an embodiment of power pulses applied to resistors. Referring to FIG. 6, during a period in which one of the row switches SW_A, SW_B, SW_C, and SW_D is turned on, column switches SW_1, SW_2, SW_3, and SW_4 may be turned on according to duty times, for example, corresponding to FIG. 5. In addition, when application of the power pulses to resistors in any one row is completed, all the column switches SW_1, SW_2, SW_3, and SW_4 are turned on and the detect pulse DP is applied to the heater array 121.

At time T0, the row switch SW_A and the column switch SW_1 are turned on. The row switch SW_A maintains a turn-on state during a given time period ΔT. The time period ΔT includes a time period in which the column switches SW_1, SW_2, SW_3, and SW_4 are sequentially turned on according to allocated duty times and are then turned on at the same time for the detect pulse DP.

While the row switch SW_A is turned on, the column switches SW_1, SW_2, SW_3, and SW_4 are turned off after being respectively turned on by the pulse widths corresponding to specific duty times D(a,1), D(a,2), D(a,3), and D(a,4) from time points T0, T1, T2, and T3. The electric power computed based on power coupling at a turn-on time point of each of the column switches SW_1, SW_2, SW_3, and SW_4 may be supplied to the resistors R0 to R15. Afterwards, at time T4, the detect pulse DP is provided to the heater array 121 while the row switch SW_A and all the column switches SW_1, SW_2, SW_3, and SW_4 are turned on. In this case, the current flowing through each of the column switches SW_1, SW_2, SW_3, and SW_4 may be measured.

At time T5, the row switch SW_B and the column switch SW_1 are turned on. While the row switch SW_B is turned on, the column switches SW_1, SW_2, SW_3, and SW_4 are sequentially turned on at time points T0, T1, T2, and T3 during allocated duty times D(b,1), D(b,2), D(b,3), and D(b,4). At T9, the column switches SW_1, SW_2, SW_3, and SW_4 are simultaneously turned on to apply the detect pulse DP.

In the present embodiment, the column switches SW_1, SW_2, SW_3, and SW_4 are turned on based on allocated duty times while each of the row switches SW_C and SW_D is turned on. The column switches SW_1, SW_2, SW_3, and SW_4 may be simultaneously turned on to apply the detect pulse DP while each of the row switches SW_C and SW_D is turned on. The power pulse PP having a duty time according to the present embodiment is supplied to the heater array 121 in the above-described manner. In addition, the detect pulse DP is applied to the heater array 121 at a time point at which the column switches SW_1, SW_2, SW_3, and SW_4 are simultaneously turned on while one row is selected, and a current or voltage signal that is generated according to the detect pulse DP is stored as a response signal to the detect pulse DP. In this case, the stored response signal may be used as data for estimating a real-time resistance value and a real-time temperature of each resistor in a selected row.

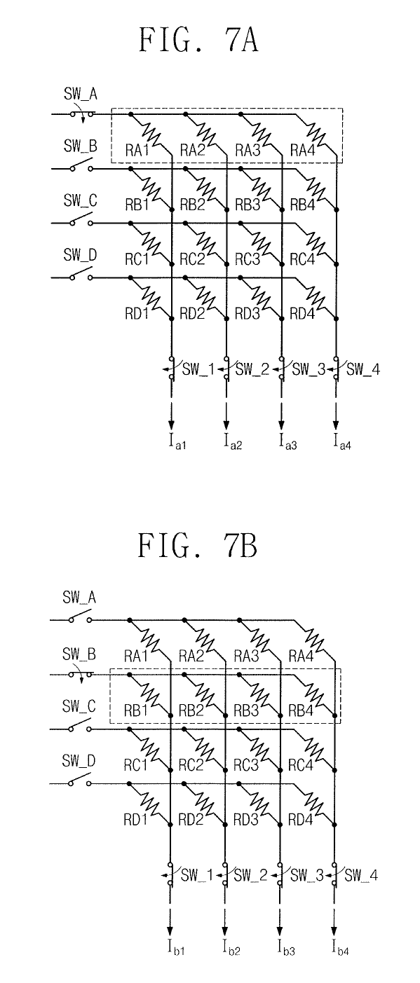

FIGS. 7A-7D illustrate an embodiment of a method for applying detect pulse DP to the heater array 121. Referring to FIGS. 7A to 7D, the detect pulse DP may be applied when all column switches are turned on and any one row switch is turned on.

FIG. 7A illustrates a switching state of the heater array 121 at a time point T4 (e.g., refer to FIG. 6) at which all the column switches SW_1, SW_2, SW_3, and SW_4 are turned on while the row switch SW_A is turned on. When the column switches SW_1, SW_2, SW_3, and SW_4 are simultaneously turned on while row switch SW_A is turned on, currents Iₐ₁, Iₐ₂, Iₐ₃, and Iₐ₄ flow through the column switches SW_1, SW_2, SW_3, and SW_4, respectively. The currents Iₐ₁, Iₐ₂, Iₐ₃, and Iₐ₄ correspond to currents flowing through the resistors RA1, RA2, RA3, RA4, respectively. The controller 180 may measure levels of the currents and may store the measured current levels.

FIG. 7B illustrates a switching state of the heater array 121 at a time point T9 (e.g., refer to FIG. 6) at which all the column switches SW_1, SW_2, SW_3, and SW_4 are turned on while the row switch SW_B is turned on. When the column switches SW_1, SW_2, SW_3, and SW_4 are simultaneously turned on while row switch SW_B is turned on, currents I_{b1}, I_{b2}, I_{b3}, and I_{b4} flow through the column switches SW_1, SW_2, SW_3, and SW_4, respectively. The currents I_{b1}, I_{b2}, I_{b3}, and I_{b4} correspond to currents flowing through the resistors RB1, RB2, RB3, RB4, respectively. The controller 180 may measure levels of the currents and may store the measured current levels.

FIG. 7C illustrates that it is possible to measure currents I_{c1}, I_{c2}, I_{c3}, and I_{c4} flowing through the resistors RC1, RC2, RC3, and RC4. FIG. 7D illustrates that it is possible to measure currents I_{d1}, I_{d2}, I_{d3}, and I_{d4} flowing through the resistors RD1, RD2, RD3, and RD4. A current flowing through each resistor may be used to calculate a real-time resistance value based on a relationship with an applied voltage. When the power pulse PP is applied to the heater array 121, the heater array 121 may be variably affected by various peripheral environmental conditions such as a heating temperature and a pressure in a chamber. A resistance value or temperature in real time may be compensated based on measurement of the real-time resistance value.

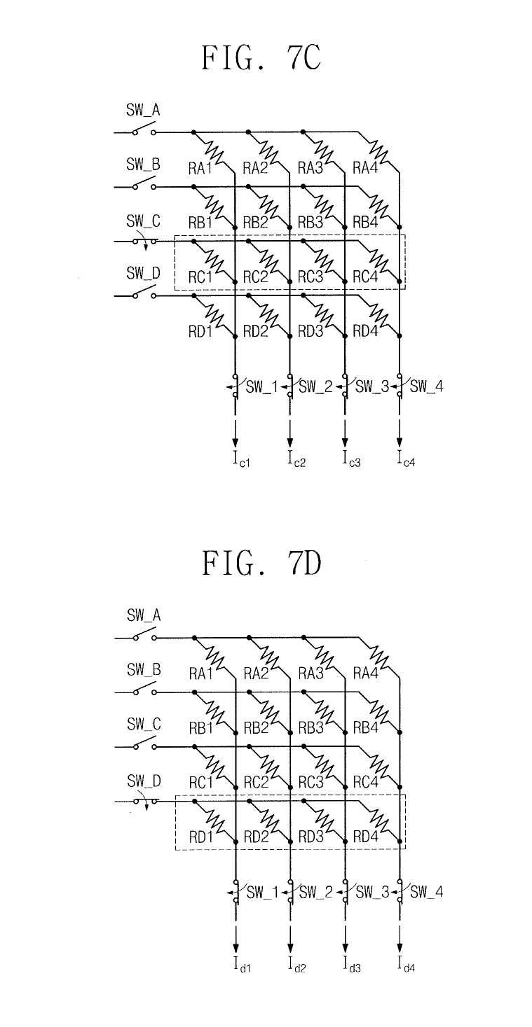

FIG. 8 illustrates an embodiment of a method for driving the micro heater 120. Referring to FIG. 8, the electrostatic chuck system 100 may monitor a temperature of the heater array 121 in real time and may again set the duty time of the power pulse PP to be applied through each switch based on the monitoring result.

In operation S110, the electric power of a given level may be applied to the macro heater 130 under control of the controller 180 (e.g., refer to FIG. 1). A refrigerant for cooling may, of course, be supplied to the chiller 140.

In operation S120, the controller 180 may control the micro driver 150 to apply the power pulse PP for heating the micro heater 120. The controller 180 may control the micro driver 150 so that a duty time of the power pulse PP to be supplied to the micro heater 120 is set to a default value D(r,c) stored in the duty time table 182. The duty time D(r,c) corresponding to the default value may correspond to a value determined in a process of manufacturing the electrostatic chuck system 100. In addition to providing the power pulse PP, the controller 180 may apply the detect pulse DP to estimate the real-time resistance value or a real-time temperature of each resistor. The detect pulse DP may be applied to the heater array 121 after the power pulse PP is provided to heat each resistor. The time point at which the detect pulse DP is applied may be different in another embodiment.

In operation S130, the controller 180 estimates a real-time resistance value of each resistor based on the detect pulse DP. For example, the controller 180 may compute a resistance value of each resistor of the heater array 121 with reference to a current value sampled by the detect pulse DP. Thus, a real-time resistance value of each resistor may be estimated using a level of a voltage applied by the detect pulse DP and a level of a current flowing through each corresponding resistor.

In operation S140, the controller 180 may reconfigure (or newly adjust) a duty time with reference to a resistance value estimated based on the detect pulse DP. Based on a resistance value monitored in real time, the controller 180 may compute a duty time using the determinant of FIG. 5 to compensate for the power coupling in the heater array 121. The computed duty time may be updated in the duty time table 182.

In operation S150, the controller 180 may provide the power pulse DP corresponding to the updated duty time to the heater array 121. The controller 180 may provide the power pulse PP by controlling the row switch 151 and the column switch 153 of the heater array 121 based on the updated duty time D(r,c). In addition, the controller 180 may apply the detect pulse DP to estimate a real-time resistance value or a real-time temperature of each resistor.

In operation S160, the controller 180 may determine whether to end a temperature control operation of the electrostatic chuck system 100. For example, the controller may determine whether a semiconductor manufacturing process performed on the wafer 101 is completed or whether a manager requests to interrupt a manufacturing process. If the semiconductor manufacturing process is not completed (No), the procedure proceeds to operation S130. If the semiconductor manufacturing process is completed or the manager requests to interrupt a manufacturing process (Yes), the temperature control operation of the electrostatic chuck system 100 ends.

In accordance with one embodiment, electrostatic chuck 110 that includes the chiller 140 and a dual-structure heater of the micro heater 120 and the macro heater 130 is controlled. In one case, due to the characteristics of the electrostatic chuck 110 at high temperatures and high pressures, it may difficult to control the target temperature of each area in real time because of a resistance change of each resistor, even though a finely computed power pulse is applied to the heater array 121. However, according to an embodiment, the detect pulse DP for estimating a real-time resistance value of each resistor is provided to the heater array 121 after the power pulse PP is applied to the heater array 121. A real-time resistance change of each resistor may be computed through the detect pulse DP, and a duty time of the power pulse PP may be updated by using the computation result.

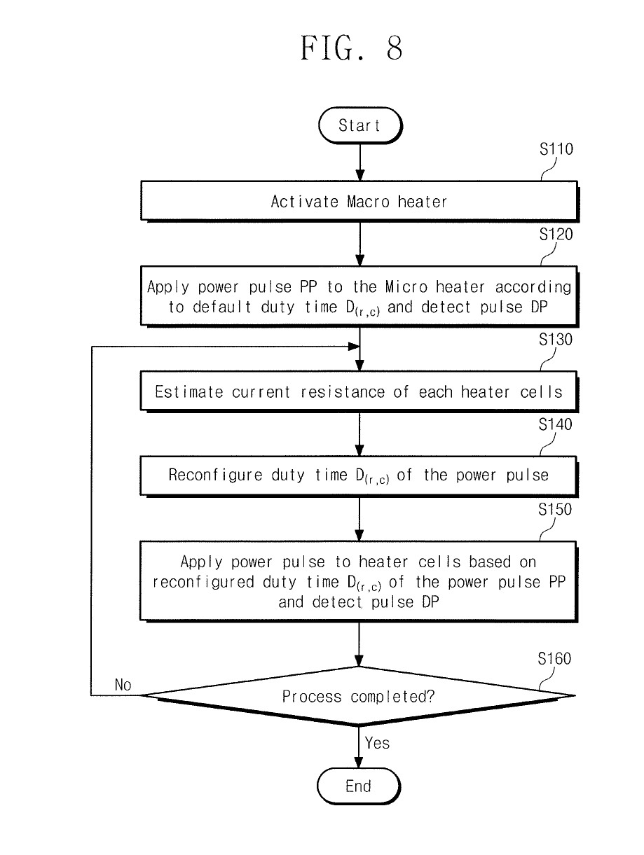

FIG. 9 illustrates an embodiment of operation S120 in FIG. 8. Referring to FIG. 9, the power pulse PP for heating a resistor and the detect pulse DP for estimating a real-time resistance value may be applied in units of rows.

In operation S122, one of the row switches SW_A, SW_B, SW_C, and SW_D of the micro heater 120 is turned on to select one row of the micro heater 120. The column switches SW_1, SW_2, SW_3, and SW_4 may be sequentially turned on according to a duty time corresponding to the default value D(r,c).

In operation S124, the detect pulse DP for estimating a real-time resistance value of each resistor corresponding to the selected row is applied to the heater array 121. The detect pulse DP may be applied to the heater array 121 by simultaneously turning on the column switches SW_1, SW_2, SW_3, and SW_4 while one of the row switches SW_A, SW_B, SW_C, and SW_D is turned on. In this case, the controller 180 may measure and store a value of a current flowing through each resistor in the selected row based on the detect pulse DP.

In operation S126, the controller 180 determines whether a row, to which the power pulse PP and the detect pulse DP are applied, is the last row of the heater array 121. If the row, to which the power pulse PP and the detect pulse DP are applied, is the last row of the heater array 121 (Yes), operation S120 may end. If the row, to which the power pulse PP and the detect pulse DP are applied, is not the last row of the heater array 121 (No), the procedure proceeds to operation S128.

In operation S128, the controller 180 changes a row of the heater array 121. For example, the controller 180 may change the location of a row switch to be turned on, e.g., another row may be selected. In operation S122, a row switch corresponding to the changed location may be turned on, and the power pulse PP may be applied to the selected row while the column switches SW_1, SW_2, SW_3, and SW_4 are sequentially turned on. In operation S124, the detect pulse DP may be applied to the heater array 121 while the column switches SW_1, SW_2, SW_3, and SW_4 are simultaneously turned on. In one embodiment, the detailed procedure of operation S120 may be equally applied to operation S150.

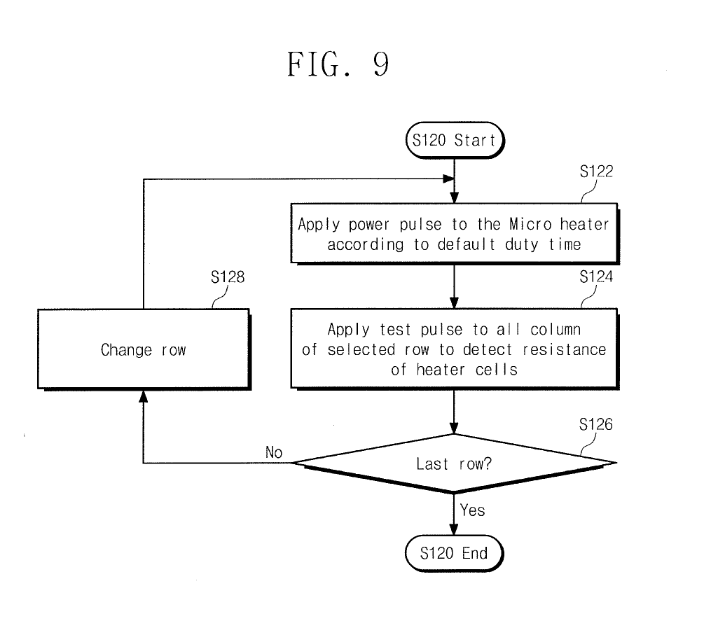

FIG. 10 illustrates another embodiment of a method for driving the micro heater 120. Referring to FIG. 10, the electrostatic chuck system 100 may monitor a temperature of each area of the heater array 121 in real time without using a temperature sensor. The electrostatic chuck system 100 may again set the duty time of the power pulse PP to be applied through a switch based on the temperature monitored in real time.

In operation S210, heating may be performed by the macro heater 130 under control of the controller 180 (e.g., refer to FIG. 1). In addition, a refrigerant for cooling may be supplied to the chiller 140.

In operation S220, the controller 180 may control the micro driver 150 to apply the power pulse PP for heating the micro heater 120. The controller 180 may control the micro driver 150 so that the power pulse PP provided to the micro heater 120 has a duty time of the default value D(r,c). The duty time D(r,c) corresponding to the default value may correspond to a value determined in a process of manufacturing the electrostatic chuck system 100. After applying the power pulse PP for heating resistors, the controller 180 may apply the detect pulse DP to estimate a real-time temperature of each resistor.

In operation S230, the controller 180 computes a change in a resistance value of each resistor due to the detect pulse DP. To this end, the controller 180 may compute a current resistance value of each resistor with reference to a current value sampled from each resistor through the detect pulse DP. The controller 180 computes the difference between a current resistance value and a previous resistance value of each resistor. The previous resistance value of each resistor may be a default resistance value or may be a resistance value detected by using the previous detect pulse DP.

In operation S240, the controller 180 estimates the temperature of an area corresponding to each resistor based on the changed resistance value of each resistor. The temperature of each resistor may be estimated based on a relationship between a temperature and a resistance value of a resistor material. For example, a temperature variation caused by resistance value changes may be computed. In one embodiment, the controller 180 may estimate the current temperature of each resistor by multiplying a rate of temperature change (° C./Ω) to a change in a resistance value with a variation (e.g., 0.02Ω) in a resistance value of any one resistor. To estimate the temperature of each resistor, a material characteristic parameter, such as the rate of temperature change (° C./Ω) to a change in a resistance value, may be provided to the controller 180.

In operation S250, the controller 180 may perform a parameter adjusting operation to adjust the temperature of the electrostatic chuck 110 based on the current temperature of each resistor. Based on the detected current temperature, the controller 180 may newly compute the duty time of the power pulse PP for driving the micro heater 120. In one embodiment, the controller 180 may generate a temperature compensation value for specific areas of the electrostatic chuck 110 by changing a parameter setting of at least one of the micro heater 120, the macro heater 130, or the chiller 140.

In operation S260, the controller 180 may drive at least one of the micro heater 120, the macro heater 130, or the chiller 140 based on a parameter set for temperature compensation.

In operation S270, the controller 180 may determine whether a manufacturing process of the electrostatic chuck system 100 is completed or whether a request to interrupt a process exists. When the manufacturing process of the electrostatic chuck system 100 is not completed or the request to interrupt a process does not exist (No), the procedure returns to operation S230. When the manufacturing process of the electrostatic chuck system 100 is completed or the request to interrupt a process exists, the temperature adjusting operation of the electrostatic chuck system 100 ends.

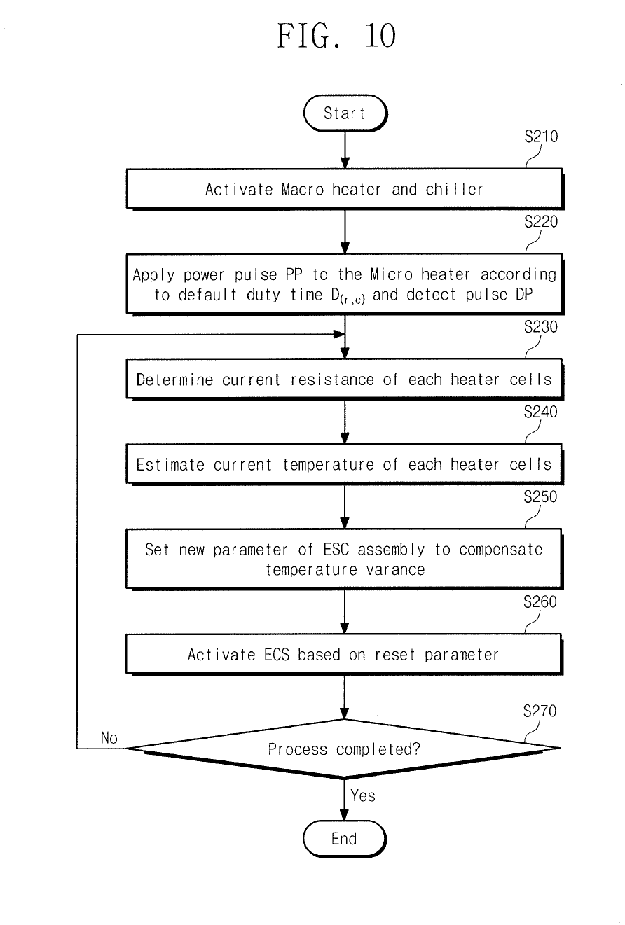

FIG. 11 illustrates a combination of the micro heater 120 and the micro driver 150 according to another embodiment. Referring to FIG. 11, the combination includes a heater array 121′ with resistors arranged in rows and columns, a row switch 151 to select the rows, a column switch 153 to select the columns, an a voltage source 155.

In this example embodiment, the heater array 121′ in FIG. 11 includes 9 resistors R0 to R8 arranged in a 3-by-3 matrix. Each of the resistors R0 to R8 of the heater array 121′ may not include a semiconductor rectifying device, e.g., a diode. The row switch 151, the column switch 153, and the voltage source 155 are configured to select the resistors R0 to R8 in the 3-by-3 matrix. The heater array 121′ may be the same as the heater array 121 in FIG. 3, except for the number of resistors.

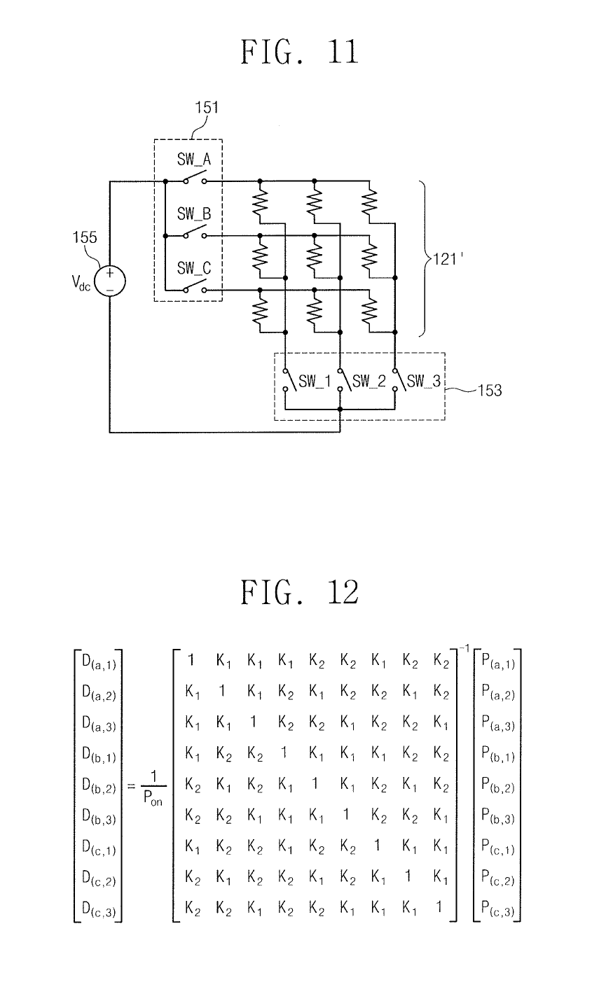

FIG. 12 illustrates a determinant of a duty time of a power pulse for controlling the micro heater 120 having a structure of FIG. 11. This determinant corresponds to a duty time of the power pulse PP to be provided to the heater array 121′ (having 9 resistors R0 to R8 arranged in a 3-by-3 matrix). The determinant of FIG. 12 corresponds to the case that the resistors R0 to R8 have the same resistance value. However, the determinant may be used even in the case where the resistors R0 to R8 have different resistance values.

Referring to FIG. 12, duty times D(a,1), D(a,2), D(a,3), D(b,1), D(b,2), D(b,3), D(c,1), D(c,2), and D(c,3) corresponding to turn-on times of the column switch 153 are expressed with a function of the whole power P_{ON} and electric powers P(a,1), P(a,2), P(a,3), P(b,1), P(b,2), P(b,3), P(c,1), P(c,2), and P(c,3) for respective resistors. In the case where the resistors R0 to R8 have the same resistance value, the determinant of FIG. 12 may be calculated, for example, based on the following equations. When the resistors R0 to R8 have different resistance values, the determinant of FIG. 12 may be determined with a final convergence value through an iterative operation.

K1 and K2 may be defined by Equations 2 and 3, respectively, in which “n” indicates the number of rows or columns.

$$\begin{matrix}{K}_{1} = \frac{{( n - 1 )}^{2}}{{( 2 n - 1 )}^{2}} & ( 2 ) \\ {K}_{2} = \frac{1}{{( 2 n - 1 )}^{2}} & ( 3 )\end{matrix}$$

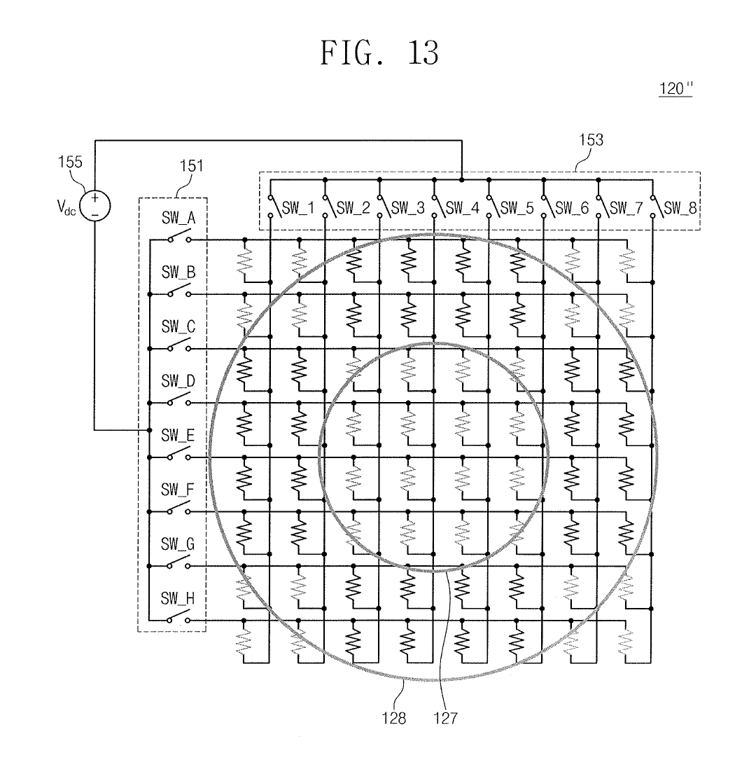

FIG. 13 illustrates a micro heater 120″ according to another embodiment. The micro heater 120″ may be expanded to have a more subdivided control structure.

Referring to FIG. 13, the micro heater 120″ may be managed as independent heater arrays with respect to concentric circles 127 and 128. For example, the micro heater 120″ may independently control resistors between the concentric circles 127 and 128 and resistors inside concentric circle 127 and outside concentric circle 128. This structure makes it easy to control temperature in connection with the macro heater 130. Also, this structure may be suitable even when a temperature control unit of the micro heater 120″ is subdivided to a greater extent. In the micro heater 120″ in FIG. 13, locations of resistors are determined according to a geometric structure of the concentric circles 127 and 128. In another embodiment, the resistors may be randomly arranged irrespective of a geometric structure of the micro heater 120″.

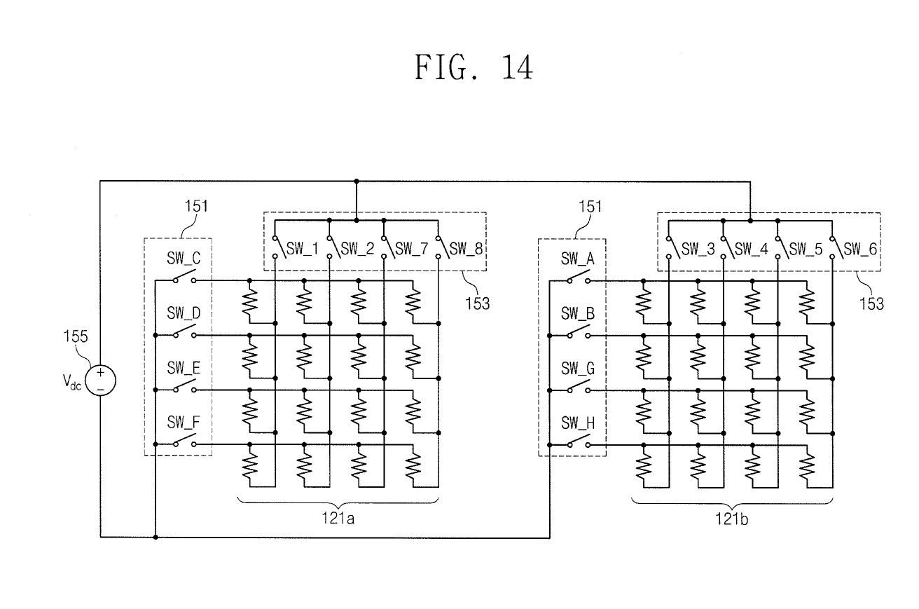

FIG. 14 illustrates an embodiment of two independent heater arrays of the micro heater 120″ having a structure of FIG. 13. Referring to FIG. 14, the micro heater 120″ may be managed in a state where the micro heater 120″ is divided into a first heater array 121a and a second heater array 121b. In order to manage the temperature of the micro heater 120″ more finely, the micro heater 120″ may include more resistors. In order to manage more resistors, the micro heater 120″ may be divided into multiple arrays. Each of the first heater array 121a and the second heater array 121b may correspond to the heater array 121 of FIG. 3, which includes four rows and four columns. Accordingly, the first heater array 121a and the second heater array 121b may be respectively controlled based on the above-described duty time computing method taking the power coupling into consideration.

In one embodiment, the first heater array 121a and the second heater array 121b may be controlled independently of each other. For example, applying the power pulse PP and the detect pulse DP to the first heater array 121a may be independent of applying the power pulse PP and the detect pulse DP to the second heater array 121b. The division of the micro heater 120″ into arrays may be performed in consideration of influence of the macro heater 130. Based on influence of the macro heater 130 having heater electrodes in a concentric direction, the first heater array 121a and the second heater array 121b may be driven at different levels of voltages or different power sources.

A 4-by-4 heater array structure and a 3-by-3 heater array structure are exemplified in the aforementioned embodiments. The number of resistors of a heater array, which are arranged in rows and columns, may be different in another embodiment. A duty time matrix, to which the power coupling of the heater array is applied, may be deducted through a matrix operation using a computer.

In addition, a method for heating a heater array and a method for monitoring a real-time resistance change or a real-time temperature change may not be limited to driving electrostatic chuck system 100. In other embodiments, these methods may be applied to other equipment for managing temperature with high accuracy by dividing a specific plane into a plurality of areas.

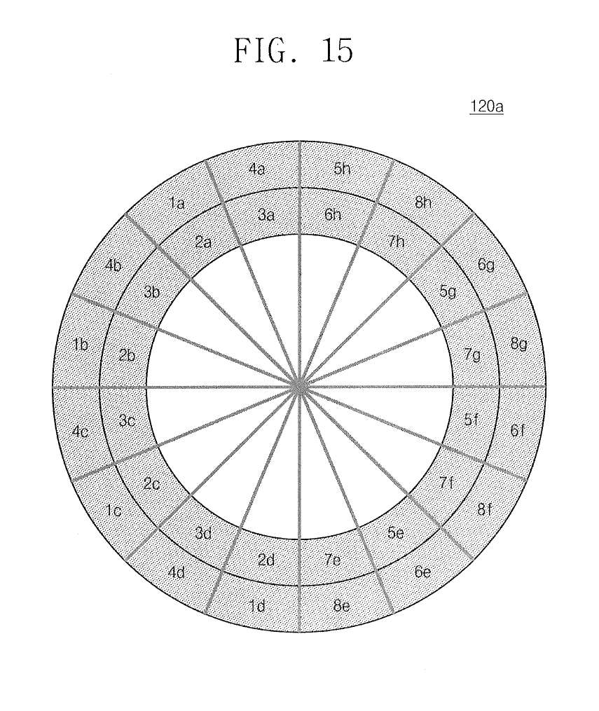

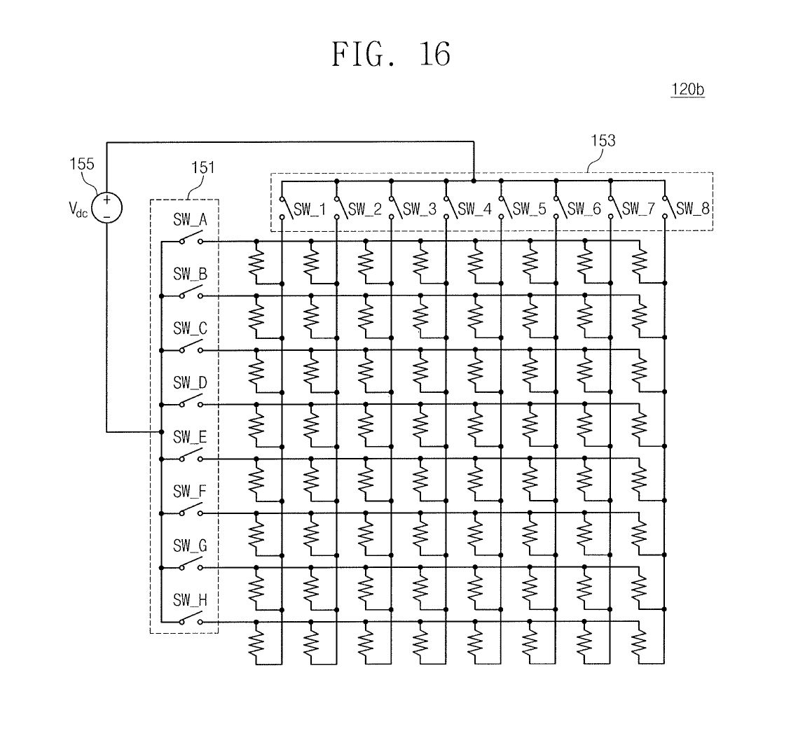

FIGS. 15 and 16 illustrate additional embodiments of a method for arranging resistors of the micro heater 120″. Referring to FIGS. 15 and 16, resistors of micro heater 120a may be arranged independently of the geometric structure of the resistor array. Even though resistors of the micro heater 120a are controlled by switches in an array, the resistors of the micro heater 120a may be arranged in concentric circle. For example, locations of resistors selected by the row switch 151 and the column switch 153 may be arranged in a concentric direction in various manners. For example, resistors 1a, 2a, 3a, and 4a selected through the row switch SW_A and the column switches SW_1, SW_2, SW_3, and SW_4 may be arranged in some of top-left concentric circles of the micro heater 120a. The arrangement of the resistors may be mapped on the micro heater 120a in various forms, for example, according to an intended application.

The methods, processes, and/or operations described herein may be performed by code or instructions to be executed by a computer, processor, controller, or other signal processing device. The computer, processor, controller, or other signal processing device may be those described herein or one in addition to the elements described herein. Because the algorithms that form the basis of the methods (or operations of the computer, processor, controller, or other signal processing device) are described in detail, the code or instructions for implementing the operations of the method embodiments may transform the computer, processor, controller, or other signal processing device into a special-purpose processor for performing the methods herein.

The controllers, estimators, calculators, drivers, and other processing features of the disclosed embodiments may be implemented in logic which, for example, may include hardware, software, or both. When implemented at least partially in hardware, the controllers, estimators, calculators, drivers, and other processing features may be, for example, any one of a variety of integrated circuits including but not limited to an application-specific integrated circuit, a field-programmable gate array, a combination of logic gates, a system-on-chip, a microprocessor, or another type of processing or control circuit.

When implemented in at least partially in software, the controllers, estimators, calculators, drivers, and other processing features may include, for example, a memory or other storage device for storing code or instructions to be executed, for example, by a computer, processor, microprocessor, controller, or other signal processing device. The computer, processor, microprocessor, controller, or other signal processing device may be those described herein or one in addition to the elements described herein. Because the algorithms that form the basis of the methods (or operations of the computer, processor, microprocessor, controller, or other signal processing device) are described in detail, the code or instructions for implementing the operations of the method embodiments may transform the computer, processor, controller, or other signal processing device into a special-purpose processor for performing the methods herein.

In accordance with one or more of the aforementioned embodiments, an electrostatic chuck system includes a heater array having a matrix structure for finely adjusting the temperature of a target area or a target point without using a semiconductor device. In addition, the electrostatic chuck system may control the temperature and electric power in real time based on a result of detecting a characteristic change of a resistor varying in real time.

Example embodiments have been disclosed herein, and although specific terms are employed, they are used and are to be interpreted in a generic and descriptive sense only and not for purpose of limitation. In some instances, as would be apparent to one of ordinary skill in the art as of the filing of the present application, features, characteristics, and/or elements described in connection with a particular embodiment may be used singly or in combination with features, characteristics, and/or elements described in connection with other embodiments unless otherwise indicated. Accordingly, it will be understood by those of skill in the art that various changes in form and details may be made without departing from the spirit and scope of the present invention as set forth in the following claims.

1. An electrostatic chuck system, comprising:
a first heater including a plurality of resistors connected to a plurality of row wiring lines and a plurality of column wiring lines in a matrix form;
a second heater under the first heater and including a heater electrode in a concentric shape or a spiral shape;
a chiller under the second heater to chill the first heater or the second heater; and
a first controller to control the first heater, the second heater, and the chiller, wherein the first controller is to switch the row wiring lines and the column wiring lines of the first heater in a time-division manner to provide a power pulse to heat the resistors and a detect pulse to monitor a real-time resistance value or a real-time temperature of each of resistors connected to selected row wiring lines.

2. The system as claimed in claim 1, wherein the first controller includes:
a power source to provide electric power for the first heater;
a plurality of row switches to connect the power source to the row wiring lines, respectively;
a plurality of column switches to connect the power source to the column wiring lines, respectively; and
a second controller to generate a switch control signal to control the row switches and the column switches in a time-division manner, wherein the switch control signal is to be generated based on duty time information corresponding to turn-on times of the row switches and the column switches generated with reference to power coupling among the resistors.

3. The system as claimed in claim 2, wherein the second controller is to:
compute electric power for each of the resistors based on the power coupling, and
determine a duty time to supply the computed electric power to each of the resistors.

4. The system as claimed in claim 3, wherein the second controller includes a duty time table to store the duty time information corresponding to each of the row switches and the column switches.

5. The system as claimed in claim 2, wherein the second controller includes:
an estimator to compute a real-time resistance value or a real-time temperature of each of the resistors based on a response of each of the resistors in response to the detect pulse.

6. The system as claimed in claim 5, wherein the estimator is to compute the real-time resistance value of each of the resistors based on a detection current from each of the resistors.

7. The system as claimed in claim 6, wherein the estimator is to adjust the duty time information based on a resistance change of each of the resistors.

8. The system as claimed in claim 5, wherein the estimator is to compute the real-time temperature with reference to a resistance change of each of the resistors and a temperature and a resistance characteristic of each of the resistors.

9. The system as claimed in claim 8, wherein the estimator is to control at least one of the first heater, the second heater, or the chiller based on the real-time temperature.

10. The system as claimed in claim 1, wherein each of the resistors excludes and is not connected to a semiconductor rectifying device.

11. A method for controlling a heater array, which includes a plurality of resistors arranged in a matrix, each of the resistors excluding and is not connected to a semiconductor rectifying device, the method comprising:
computing a duty time of each of a plurality of row switches and a plurality of column switches based on mutual power coupling of the resistors, the row and column switches supplying electric power to heat each of the resistors;
applying electric power to the resistors by sequentially turning on the row switches and the column switches based on the duty time;
applying a detect pulse to each of the resistors; and
estimating a real-time resistance value or a real-time temperature of each of the resistors with reference to the detect pulse.

12. The method as claimed in claim 11, wherein the detect pulse is provided to the resistors by simultaneously turning on the column switches while one of the row switches is turned on.

13. The method as claimed in claim 11, further comprising:
adjusting the duty time based on the real-time resistance value or the real-time temperature of each of the resistors.

14. The method as claimed in claim 13, further comprising:
applying a power pulse to the resistors based on the adjusted duty time.

15. An electrostatic chuck system, comprising:
an electrostatic chuck includes a micro heater and a macro heater, the micro heater including a plurality of resistors connected in a matrix form and the macro heater including a heater electrode in a concentric shape or a spiral shape; and
a controller to control heating power to the micro heater or the macro heater, wherein the controller is to provide a time-division power pulse, to which mutual power coupling among the resistors is applied, provide a detect pulse to detect a characteristic change of each of the resistors, and update a pulse width of the power pulse based on a response to the detect pulse.

16. The system as claimed in claim 15, wherein the controller is to provide a duty time of the time-division power pulse to heat each of the resistors at a target temperature.

17. The system as claimed in claim 16, wherein the controller is to connect a power source with rows and columns of the resistors based on the duty time.

18. The system as claimed in claim 16, wherein the controller is to estimate a real-time resistance value or a real-time temperature of each of the resistors based on a response to the detect pulse.

19. The system as claimed in claim 18, wherein the controller is to update the duty time based on the estimated real-time resistance value or the estimated real-time temperature.

20. The system as claimed in claim 15, wherein each of the resistors excludes and is not connected to a semiconductor rectifying device.

21-25. (canceled)
